(19) United States
(12) Patent Application Publication
(10) Pub. No.: US 2025/0146177 A1
(43) Pub. Date: May 8, 2025

(54) SILICON CARBIDE EPITAXIAL SUBSTRATE

(71) Applicant: SUMITOMO ELECTRIC INDUSTRIES, LTD., Osaka (JP)

(72) Inventors: Kyoko OKITA, Osaka (JP); Naoki KAJI, Osaka (JP); Tsubasa HONKE, Osaka (JP)

(73) Assignee: SUMITOMO ELECTRIC INDUSTRIES, LTD., Osaka (JP)

(21) Appl. No.: 18/833,358

(22) PCT Filed: Jan. 12, 2023
(86) PCT No.: PCT/JP2023/000648

§ 371 Date: Jul. 25, 2024

(30) Foreign Application Priority Data
Feb. 2, 2022 (JP) 2022-014815

(51) Int. Cl. C30B 29/36

(52) U.S. Cl. CPC C30B 29/36

(57) ABSTRACT

A silicon carbide epitaxial substrate includes a silicon carbide substrate and a silicon carbide epitaxial layer. The silicon carbide substrate has a first main surface. The silicon carbide epitaxial layer is provided on the first main surface. The silicon carbide epitaxial layer has one or more blue light-emitting defects. The silicon carbide epitaxial layer has a second main surface. The second main surface is located opposite to an interface between the silicon carbide substrate and the silicon carbide epitaxial layer. The one or more blue light-emitting defects are exposed at the second main surface. When an area density of one or more threading screw dislocations in the first main surface is a first area density, an area density of one or more threading edge dislocations in the first main surface is a second area density, and an area density of the one or more blue light-emitting defects in the second main surface is a third area density, a ratio of the third area density to a sum of the first area density and the second area density is 0.03% or less.

### TECHNICAL FIELD

The present disclosure relates to a silicon carbide epitaxial substrate. The present application claims priority based on Japanese Patent Application No. 2022-014815 filed on Feb. 2, 2022, the entire contents of which are incorporated herein by reference.

### BACKGROUND ART

Japanese Patent Laying-Open No. 2009-292723 (PTL 1) discloses a silicon carbide epitaxial substrate having a low threading dislocation density in a silicon carbide substrate.

### CITATION LIST

### Patent Literature

PTL 1: Japanese Patent Laying-Open No. 2009-292723

### SUMMARY OF INVENTION

A silicon carbide epitaxial substrate according to the present disclosure includes a silicon carbide substrate and a silicon carbide epitaxial layer. The silicon carbide substrate has a first main surface. The silicon carbide epitaxial layer is provided on the first main surface. The silicon carbide substrate has one or more threading screw dislocations. The silicon carbide substrate has one or more threading edge dislocations. The silicon carbide epitaxial layer has one or more blue light-emitting defects. The silicon carbide epitaxial layer has a second main surface. The second main surface is located opposite to an interface between the silicon carbide substrate and the silicon carbide epitaxial layer. The one or more blue light-emitting defects are exposed at the second main surface. When photoluminescence light generated from the one or more blue light-emitting defects by irradiation of the one or more blue light-emitting defects with excitation light is represented in HSV color space, H is 180° or more and 230° or less, S is 60 or more and 170 or less, and Vis 190 or more and 255 or less. When the first main surface is divided into a plurality of square regions each having a side length of 10 mm, the plurality of square regions include a plurality of first outer circumferential regions located at an outermost circumference of the plurality of square regions, and a plurality of second outer circumferential regions in contact with the plurality of first outer circumferential regions. An average value of LTIR of the silicon carbide substrate in the plurality of first outer circumferential regions and the plurality of second outer circumferential regions is 0.6 μm or less. When an area density of the one or more threading screw dislocations in the first main surface is a first area density, an area density of the one or more threading edge dislocations in the first main surface is a second area density, and an area density of the one or more blue light-emitting defects in the second main surface is a third area density, a ratio of the third area density to a sum of the first area density and the second area density is 0.03% or less.

### BRIEF DESCRIPTION OF DRAWINGS

FIG. 1 is a schematic plan view showing a configuration of a silicon carbide epitaxial substrate according to the present embodiment.

FIG. 2 is a schematic cross-sectional view along a line II-II in FIG. 1.

FIG. 3 is a schematic enlarged cross-sectional view showing a region III in FIG. 2.

FIG. 4 is a schematic diagram showing a configuration of a color photoluminescence imaging apparatus.

FIG. 5 is a schematic plan view showing a measurement region of LTIR.

FIG. 6 is a schematic diagram illustrating the definition of the LTIR.

FIG. 7 is a schematic cross-sectional view along a line VII-VII in FIG. 5.

FIG. 8 is a schematic cross-sectional view illustrating the definition of total thickness variation.

FIG. 9 is a flow chart schematically showing a method for manufacturing the silicon carbide epitaxial substrate according to the present embodiment.

FIG. 10 is a schematic cross-sectional view showing a configuration of a silicon carbide wafer.

FIG. 11 is a schematic enlarged view showing a region XI in FIG. 10.

FIG. 12 is a schematic plan view showing a configuration of a polishing apparatus.

FIG. 13 is a schematic front view showing the configuration of the polishing apparatus.

FIG. 14 is a schematic enlarged cross-sectional view showing a configuration of a dummy wafer during a required amount of polishing determination step.

FIG. 15 is a schematic enlarged plan view showing the configuration of the dummy wafer during the required amount of polishing determination step.

FIG. 16 is a schematic enlarged view showing the configuration of the dummy wafer after the required amount of polishing determination step.

FIG. 17 is a schematic enlarged view showing a configuration of a silicon carbide substrate in a polishing step.

FIG. 18 is a schematic enlarged cross-sectional view showing a state in which a silicon carbide epitaxial layer is formed after polishing has been performed so as to obtain a sufficiently low surface roughness of a first main surface of the silicon carbide substrate.

FIG. 19 is a schematic cross-sectional view showing a state in which the amount of polishing by mechanical polishing in the polishing step is excessively large.

### DETAILED DESCRIPTION

### [Problem to be Solved by the Present Disclosure]

An object of the present disclosure is to provide a silicon carbide epitaxial substrate that can improve the yield of a silicon carbide semiconductor device.

### [Advantageous Effect of the Present Disclosure]

According to the present disclosure, there can be provided a silicon carbide epitaxial substrate that can improve the yield of a silicon carbide semiconductor device.

### Description of Embodiments

Initially, embodiments of the present disclosure are described one by one.

(1) A silicon carbide epitaxial substrate 100 according to the present disclosure includes a silicon carbide substrate 10 and a silicon carbide epitaxial layer 20. Silicon carbide substrate 10 has a first main surface 1. Silicon carbide epitaxial layer 20 is provided on first main surface 1. Silicon carbide substrate 10 has one or more threading screw dislocations 81. Silicon carbide substrate 10 has one or more threading edge dislocations 82. Silicon carbide epitaxial layer 20 has one or more blue light-emitting defects 83. Silicon carbide epitaxial layer 20 has a second main surface 2. Second main surface 2 is located opposite to an interface 6 between silicon carbide substrate 10 and silicon carbide epitaxial layer 20. One or more blue light-emitting defects 83 are exposed at second main surface 2. When photoluminescence light generated from one or more blue light-emitting defects 83 by irradiation of one or more blue light-emitting defects 83 with excitation light is represented in HSV color space, H is 180° or more and 230° or less, S is 60 or more and 170 or less, and Vis 190 or more and 255 or less. When first main surface 1 is divided into a plurality of square regions 50 each having a side length of 10 mm, the plurality of square regions 50 include a plurality of first outer circumferential regions 61 located at an outermost circumference of the plurality of square regions 50, and a plurality of second outer circumferential regions 62 in contact with the plurality of first outer circumferential regions 61. An average value of LTIR of silicon carbide substrate 10 in the plurality of first outer circumferential regions 61 and the plurality of second outer circumferential regions 62 is 0.6 μm or less. When an area density of one or more threading screw dislocations 81 in first main surface 1 is a first area density, an area density of one or more threading edge dislocations 82 in first main surface 1 is a second area density, and an area density of one or more blue light-emitting defects 83 in second main surface 2 is a third area density, a ratio of the third area density to a sum of the first area density and the second area density is 0.03% or less.

(2) In silicon carbide epitaxial substrate 100 according to (1) described above, silicon carbide substrate 10 may have a total thickness variation of 6 μm or less.

(3) In silicon carbide epitaxial substrate 100 according to (1) or (2) described above, the ratio of the third area density to the sum of the first area density and the second area density may be 0.02% or less.

(4) In silicon carbide epitaxial substrate 100 according to (3) described above, the ratio of the third area density to the sum of the first area density and the second area density may be 0.01% or less.

(5) In silicon carbide epitaxial substrate 100 according to any one of (1) to (4) described above, a ratio of the third area density to the first area density may be 0.2% or less.

(6) In silicon carbide epitaxial substrate 100 according to any one of (1) to (5) described above, the first area density may be 1500/cm² or less.

(7) In silicon carbide epitaxial substrate 100 according to (6) described above, the first area density may be 500/cm² or less.

(8) In silicon carbide epitaxial substrate 100 according to (7) described above, the first area density may be 100/cm² or less.

(9) In silicon carbide epitaxial substrate 100 according to any one of (1) to (8) described above, the second area density may be 10000/cm² or less.

(10) In silicon carbide epitaxial substrate 100 according to (9) described above, the second area density may be 5000/cm² or less.

(11) In silicon carbide epitaxial substrate 100 according to (10) described above, the second area density may be 2000/cm² or less.

(12) In silicon carbide epitaxial substrate 100 according to any one of (1) to (11) described above, second main surface 2 may have a diameter D of 150 mm or more.

(13) In silicon carbide epitaxial substrate 100 according to any one of (1) to (12) described above, silicon carbide substrate 10 may have an electrical resistivity of 10 mΩ·cm or more.

### [Details of Embodiments of the Present Disclosure]

Hereinafter, embodiments of the present disclosure will be described in detail based on the drawings. It should be noted that, in the drawings below, identical or corresponding parts are denoted by the same reference numerals, and the description thereof will not be repeated. Regarding crystallographic indications in the present specification, an individual orientation is represented by [ ], a group orientation is represented by < >, an individual plane is represented by ( ) and a group plane is represented by { }. Generally, a negative index is supposed to be crystallographically indicated by putting “-” (bar) above a numeral, but is indicated by putting the negative sign before the numeral in the present specification.

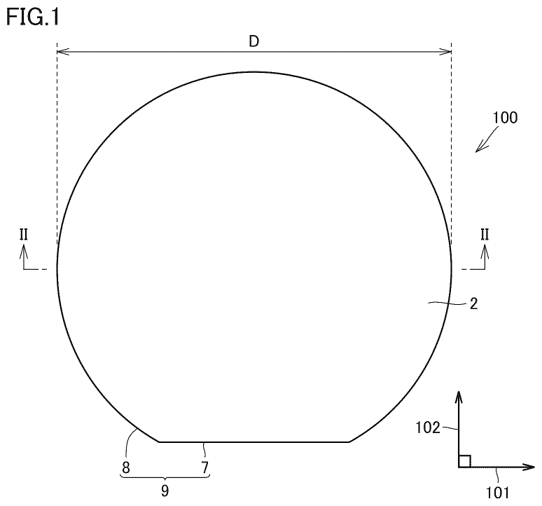

First, a configuration of a silicon carbide epitaxial substrate according to the present embodiment is described. FIG. 1 is a schematic plan view showing the configuration of the silicon carbide epitaxial substrate according to the present embodiment. As shown in FIG. 1, a silicon carbide epitaxial substrate 100 has a second main surface 2 and an outer circumferential side surface 9. Second main surface 2 extends along each of a first direction 101 and a second direction 102. First direction 101 is not particularly limited, and is a <11-20> direction, for example. Second direction 102 is not particularly limited, and is a <1-100> direction, for example. Outer circumferential side surface 9 is contiguous to second main surface 2. Silicon carbide epitaxial substrate 100 is made of hexagonal silicon carbide, for example. The hexagonal silicon carbide has a polytype of 4H, for example.

Second main surface 2 is a plane inclined relative to a {0001} plane. An off angle of second main surface 2 relative to the {0001} plane may be 8° or less, for example. Specifically, second main surface 2 may be a plane inclined at an off angle of 8° or less relative to a (0001) plane. Second main surface 2 may be a plane inclined at an off angle of 8° or less relative to a (000-1) plane. An inclination direction (off direction) of second main surface 2 relative to the {0001} plane is the <11-20> direction, for example. The off angle of second main surface 2 relative to the {0001} plane is not particularly limited, and may be 7° or less, or 6° or less, for example. The off angle of second main surface 2 relative to the {0001} plane is not particularly limited, and may be 1° or more, or 2° or more, for example.

As shown in FIG. 1, outer circumferential side surface 9 has an orientation flat portion 7 and an arc-shaped portion 8. Arc-shaped portion 8 is contiguous to orientation flat portion 7. As shown in FIG. 1, orientation flat portion 7 may extend along first direction 101 as seen in a direction perpendicular to second main surface 2.

Second main surface 2 has a diameter D of 150 mm or more, for example. Diameter D is not particularly limited, and may be 200 mm or more, or 250 mm or more, for example. Diameter D is not particularly limited, and may be 300 mm or less, for example. Diameter D is the longest linear distance between two different points on outer circumferential side surface 9 as seen in the direction perpendicular to second main surface 2.

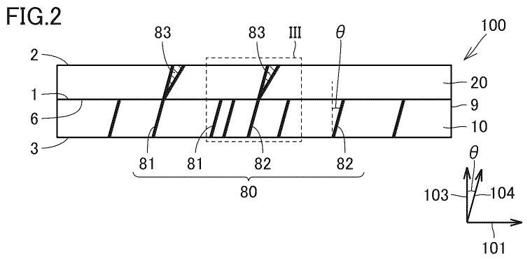

FIG. 2 is a schematic cross-sectional view along a line II-II in FIG. 1. The cross section shown in FIG. 2 is perpendicular to second main surface 2, and parallel to first direction 101. As shown in FIG. 2, silicon carbide epitaxial substrate 100 according to the present embodiment includes a silicon carbide substrate 10 and a silicon carbide epitaxial layer 20. Silicon carbide epitaxial layer 20 is provided on silicon carbide substrate 10. Silicon carbide epitaxial layer 20 is in contact with silicon carbide substrate 10. Silicon carbide substrate 10 has a polytype of 4H, for example. Similarly, silicon carbide epitaxial layer 20 has a polytype of 4H, for example.

Silicon carbide epitaxial layer 20 forms second main surface 2 of silicon carbide epitaxial substrate 100. Second main surface 2 is located opposite to an interface 6. Interface 6 is located at a boundary between silicon carbide substrate 10 and silicon carbide epitaxial layer 20. Silicon carbide substrate 10 has a first main surface 1 and a third main surface 3. Silicon carbide substrate 10 is in contact with silicon carbide epitaxial layer 20 at first main surface 1. In other words, silicon carbide epitaxial layer 20 is provided on first main surface 1. Third main surface 3 is located opposite to first main surface 1. Second main surface 2 is a front surface of silicon carbide epitaxial substrate 100. Third main surface 3 is a back surface of silicon carbide epitaxial substrate 100.

First main surface 1 may have polishing marks. Each polishing mark has an elongate shape as seen in a direction perpendicular to first main surface 1. The polishing mark has a longitudinal length that is ten times or more its lateral length. The polishing mark may be linear or curved. The polishing mark has a length of 0.5 mm or more, for example, as seen in the direction perpendicular to first main surface 1. The polishing mark has a depth of 0.5 μm or more, for example, in the direction perpendicular to first main surface 1. An area density of the polishing marks in first main surface 1 is 1/cm² or less, for example. The polishing mark on first main surface 1 can be identified using a laser microscope, a white light interference microscope, or a defect inspection device such as “SICA 6X” of the WASAVI series manufactured by Lasertec Corporation. Specifically, a groove intersecting a linear stripe extending in the <1-100> direction is identified as a polishing mark, as observed from above second main surface 2 of silicon carbide epitaxial layer 20.

As shown in FIG. 2, silicon carbide substrate 10 has a plurality of threading dislocations 80. The plurality of threading dislocations 80 are formed by a plurality of threading screw dislocations 81 and a plurality of threading edge dislocations 82.

Each of the plurality of threading dislocations 80 continuously extends from third main surface 3 to first main surface 1. Each of the plurality of threading dislocations 80 extends in a fourth direction 104. Fourth direction 104 is a <0001> direction, for example. A third direction 103 is a direction perpendicular to second main surface 2. From a different viewpoint, third direction 103 is a direction perpendicular to each of first direction 101 and second direction 102. An inclination angle θ of fourth direction 104 relative to third direction 103 corresponds to the off angle of second main surface 2. Each of the plurality of threading dislocations 80 is exposed at third main surface 3.

As shown in FIG. 2, silicon carbide epitaxial layer 20 has a plurality of blue light-emitting defects 83. Each of the plurality of blue light-emitting defects 83 is formed due to threading dislocation 80. Each of the plurality of blue light-emitting defects 83 is contiguous to threading dislocation 80 at first main surface 1. Each of the plurality of blue light-emitting defects 83 may be contiguous to threading screw dislocation 81, or may be contiguous to threading edge dislocation 82. Each of the plurality of blue light-emitting defects 83 continuously extends from interface 6 to second main surface 2. Each of the plurality of blue light-emitting defects 83 has a width in first direction 101 that increases as the distance from interface 6 increases. Each of the plurality of blue light-emitting defects 83 is triangular, for example, as seen in a direction perpendicular to each of first direction 101 and third direction 103. Each of the plurality of blue light-emitting defects 83 is exposed at second main surface 2.

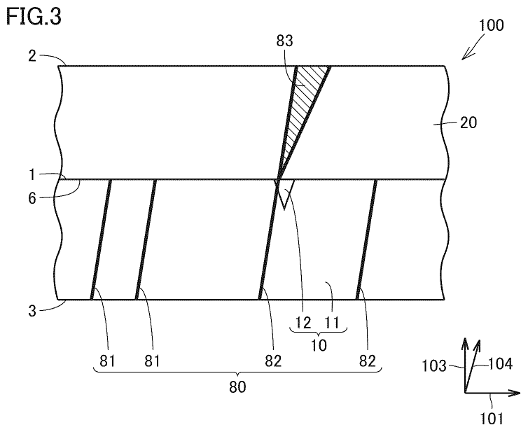

FIG. 3 is a schematic enlarged cross-sectional view showing a region III in FIG. 2. As shown in FIG. 3, silicon carbide substrate 10 is formed by a normal portion 11 and a damaged portion 12. Normal portion 11 is a portion made of a normal crystal lattice that has not suffered processing damage by slicing. Damaged portion 12 is a portion of a disrupted arrangement of the crystal lattice of silicon carbide substrate 10 due to processing damage by slicing. Damaged portion 12 is contiguous to normal portion 11. Damaged portion 12 forms part of first main surface 1 of silicon carbide substrate 10. From a different viewpoint, damaged portion 12 is in contact with silicon carbide epitaxial layer 20. Damaged portion 12 is provided in the vicinity of threading dislocation 80.

Each of the plurality of blue light-emitting defects 83 is formed due to damaged portion 12. From a different viewpoint, each of the plurality of blue light-emitting defects 83 is contiguous to damaged portion 12. Each of the plurality of blue light-emitting defects 83 is a triangular defect, for example. Each of the plurality of blue light-emitting defects 83 may include a stacking fault. Blue light-emitting defect 83 has a triangular shape, for example, as seen in the direction perpendicular to second main surface 2.

### (Area Density of Each of Threading Screw Dislocations and Threading Edge Dislocations)

An area density of threading screw dislocations 81 in first main surface 1 is referred to as a first area density. The first area density is 1500/cm² or less, for example. The first area density is not particularly limited, and may be 1000/cm² or less, 500/cm² or less, or 100/cm² or less, for example. The first area density is not particularly limited, and may be 10/cm² or more, or 50/cm² or more, for example.

An area density of threading edge dislocations 82 in first main surface 1 is referred to as a second area density. The second area density is 10000/cm² or less, for example. The second area density is not particularly limited, and may be 5000/cm² or less, or 2000/cm² or less, for example. The second area density is not particularly limited, and may be 100/cm² or more, or 500/cm² or more, for example.

Next, a method for measuring the area density of each of threading screw dislocations 81 and threading edge dislocations 82 is described.

The area density of each of threading screw dislocations 81 and threading edge dislocations 82 is determined using molten potassium hydroxide (KOH), for example. Specifically, silicon carbide epitaxial layer 20 is removed by mechanical polishing or the like. This exposes first main surface 1 of silicon carbide substrate 10. First main surface 1 is etched with molten KOH. This etches a silicon carbide region near each of threading screw dislocation 81 and threading edge dislocation 82 exposed at first main surface 1, to thereby form etch pits in first main surface 1. A value determined by dividing the number of etch pits formed in first main surface 1 by a measurement area of first main surface 1 corresponds to the area density of each of threading screw dislocations 81 and threading edge dislocations 82 in first main surface 1. The KOH melt has a temperature of about 500° C. or more and 550° C. or less, for example. The etching is performed for about 5 minutes or more and 10 minutes or less. After the etching, first main surface 1 is observed with a Nomarski differential interference microscope.

If silicon carbide substrate 10 includes basal plane dislocations in addition to threading screw dislocations 81 and threading edge dislocations 82, a silicon carbide region near each basal plane dislocation exposed at first main surface 1 is also etched. An etch pit caused by threading screw dislocation 81, an etch pit caused by threading edge dislocation 82, and an etch pit caused by the basal plane dislocation are distinguished from one another by the following method. The etch pit caused by the basal plane dislocation has an elliptical planar shape. The etch pit caused by threading screw dislocation 81 has a round or hexagonal planar shape, and a large pit size. The etch pit caused by threading edge dislocation 82 has a round or hexagonal planar shape, and a small pit size.

### (Area Density of Blue Light-Emitting Defects)

An area density of blue light-emitting defects 83 in second main surface 2 is referred to as a third area density. The third area density is 2/cm² or less, for example. The third area density is not particularly limited, and may be 1/cm² or less, or 0.5/cm² or less, for example. The third area density is not particularly limited, and may be 0.05/cm² or more, or 0.07/cm² or more, for example.

A ratio of the third area density to the sum of the first area density and the second area density is 0.03% or less, for example. The ratio of the third area density to the sum of the first area density and the second area density is not particularly limited, and may be 0.02% or less, or 0.01% or less, for example. The ratio of the third area density to the sum of the first area density and the second area density is not particularly limited, and may be 0.001% or more, or 0.005% or more, for example.

A ratio of the third area density to the first area density is 0.2% or less, for example. The ratio of the third area density to the first area density may be 0.15% or less, or 0.1% or less. The ratio of the third area density to the first area density is not particularly limited, and may be 0.01% or more, or 0.05% or more, for example.

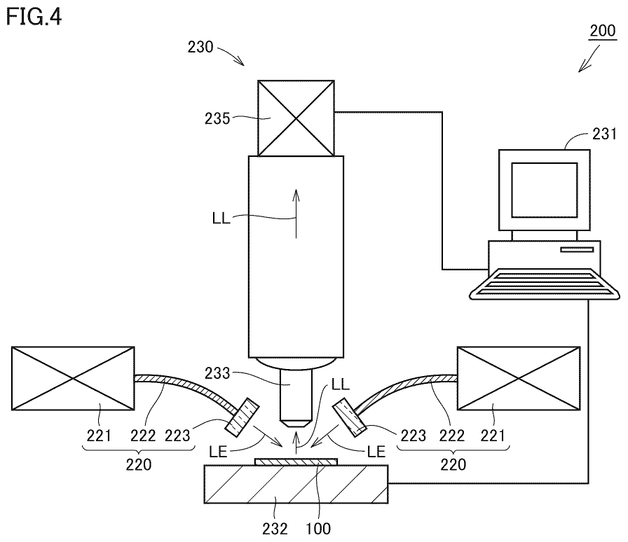

Blue light-emitting defect 83 can be identified by a photoluminescence imaging apparatus. FIG. 4 is a schematic diagram showing a configuration of a color photoluminescence imaging apparatus. A PL imaging apparatus (SemiScope™ PLI-200) manufactured by Photon Design Corporation can be used, for example, as the color photoluminescence imaging apparatus. As shown in FIG. 4, a color photoluminescence imaging apparatus 200 mainly includes an excitation light generation unit 220 and an imaging unit 230.

Excitation light generation unit 220 includes a light source unit 221, a light guiding unit 222, and a filter unit 223. Light source unit 221 can generate excitation light LE having energy higher than the band gap of hexagonal silicon carbide. Light source unit 221 is a mercury xenon lamp, for example. Light guiding unit 222 can guide light emitted from light source unit 221 such that second main surface 2 of silicon carbide epitaxial substrate 100 (see FIG. 2) is irradiated with the light. Light guiding unit 222 has optical fibers, for example. As shown in FIG. 4, excitation light generation unit 220 may be disposed on each side of a near-infrared objective lens 233.

Filter unit 223 selectively transmits light having a specific wavelength corresponding to energy higher than the band gap of hexagonal silicon carbide. A wavelength corresponding to the band gap of hexagonal silicon carbide is typically about 390 nm. Thus, a band-pass filter that particularly transmits light having a wavelength of about 313 nm, for example, is used as filter unit 223. Filter unit 223 may have a transmission wavelength range of 290 nm or more and 370 nm or less, 300 nm or more and 330 nm or less, or 300 nm or more and 320 nm or less, for example.

Imaging unit 230 mainly includes a controller 231, a stage 232, near-infrared objective lens 233, and a color image sensor 235. Controller 231 controls an operation of displacing stage 232, and controls an imaging operation by color image sensor 235, and is implemented as a personal computer, for example. Stage 232 supports silicon carbide epitaxial substrate 100 such that second main surface 2 is exposed. Stage 232 is an X-Y stage to displace the position of second main surface 2, for example. Near-infrared objective lens 233 is disposed above second main surface 2. Near-infrared objective lens 233 has a magnification of 4.5×, for example. Color image sensor 235 receives photoluminescence light emitted from silicon carbide epitaxial substrate 100.

Next, a method for identifying blue light-emitting defect 83 is described.

First, excitation light generation unit 220 is used to irradiate second main surface 2 of silicon carbide epitaxial substrate 100 with excitation light LE. Photoluminescence light LL is thereby generated from silicon carbide epitaxial substrate 100. Excitation light LE has a wavelength of 313 nm, for example. Excitation light LE has an intensity of 1 mW/cm² or more and 2 W/cm² or less, for example. The exposure time of the irradiated light is 0.5 seconds or more and 120 seconds or less, for example. Measurement is performed at room temperature (27° C.), for example.

Then, the photoluminescence light is detected by a color image sensor. Specifically, photoluminescence light LL generated at silicon carbide epitaxial substrate 100 is detected by color image sensor 235. Color image sensor 235 is a charge coupled device (CCD) image sensor, for example. The CCD device is of a back-illuminated deep depletion type, for example. The CCD image sensor is eXcelon™ manufactured by Teledyne, for example. The imaging wavelength range is 310 nm or more and 1024 nm or less, for example. The device format is 1024 ch×1024 ch, for example. The image area is 13.3 mm×13.3 mm, for example. The device size is 13 μm×13 μm, for example. The number of pixels is 480 pixels×640 pixels, for example. The image size is 1.9 mm×2.6 mm, for example.

Based on a color image obtained from color image sensor 235, the optical characteristic of blue light-emitting defect 83 is identified. The color of the image of blue light-emitting defect 83 obtained from the color image sensor is blue, for example. Specifically, when photoluminescence light generated from blue light-emitting defect 83 by irradiation of blue light-emitting defect 83 with excitation light is represented in HSV color space, H is 180° or more and 230° or less, S is 60 or more and 170 or less, and Vis 190 or more and 255 or less.

The HSV color space is one method for representing a color by hue, saturation and value. In the HSV color space, H is in a range of 0° or more and 360° or less, S is in a range of 0 or more and 255 or less, and V is in a range of 0 or more and 255 or less. Note that S and V are represented by decimal numbers, for example.

### (Degree of Sag of Silicon Carbide Substrate)

Next, the degree of sag of an outer circumferential portion of silicon carbide substrate 10 is described. The degree of sag of silicon carbide substrate 10 can be quantified using an indicator called local total indicated reading (LTIR) or total thickness variation (TTV). Each of the LTIR and TTV can be measured using a flatness measuring machine “Tropel FlatMaster™” manufactured by Corning Tropel Corporation, for example.

### (LTIR of Silicon Carbide Substrate)

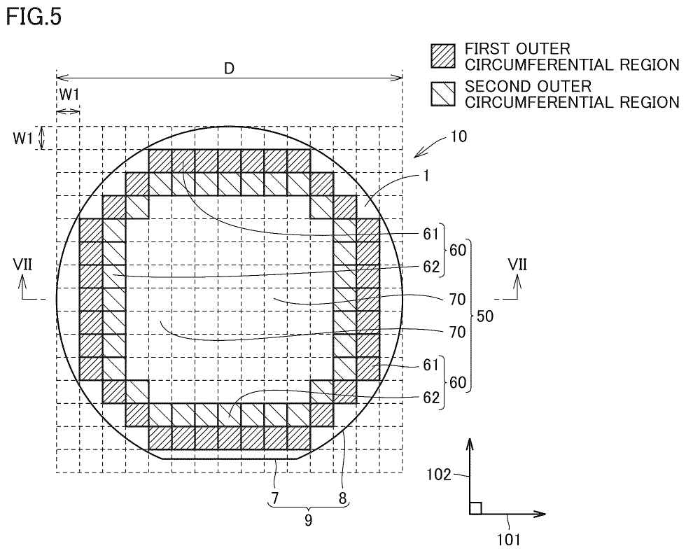

FIG. 5 is a schematic plan view showing a measurement region of the LTIR. As shown in FIG. 5, first main surface 1 of silicon carbide substrate 10 is divided into a plurality of square regions 50. Each of the plurality of square regions 50 has a side length (first length W1) of 10 mm. First main surface 1 has a diameter D of 150 mm, for example. First, a 150 mm×150 mm square circumscribing outer circumferential side surface 9 is assumed. The 150 mm×150 mm square is divided into 10 mm×10 mm square regions (15×15=225 square regions).

The number of square regions 50 surrounded by outer circumferential side surface 9 is 145, as seen in the direction perpendicular to first main surface 1. Square regions intersecting outer circumferential side surface 9 are partially missing and are not complete square regions, as seen in the direction perpendicular to first main surface 1. Therefore, the square regions intersecting outer circumferential side surface 9 are not regarded as square regions 50 forming first main surface 1. One side of each of the plurality of square regions 50 is parallel to the direction in which orientation flat portion 7 extends, as seen in the direction perpendicular to first main surface 1.

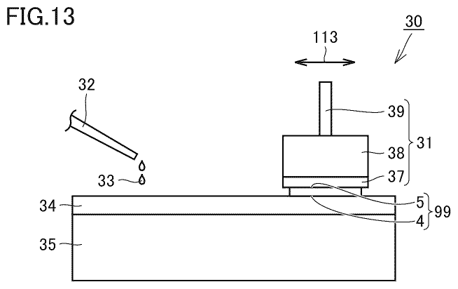

The plurality of square regions 50 are formed by a plurality of outer circumferential regions 60 and a plurality of central regions 70. The plurality of outer circumferential regions 60 are formed by a plurality of first outer circumferential regions 61 and a plurality of second outer circumferential regions 62. The plurality of first outer circumferential regions 61 are located at the outermost circumference of the plurality of square regions 50. From a different viewpoint, each of the plurality of first outer circumferential regions 61 is square region 50 in contact with a square region intersecting outer circumferential side surface 9. Each of the plurality of second outer circumferential regions 62 is square region 50 in contact with the plurality of first outer circumferential regions 61. Each of the plurality of second outer circumferential regions 62 is located on the inner side of the plurality of first outer circumferential regions 61. Each of the plurality of second outer circumferential regions 62 is spaced from the square regions intersecting outer circumferential side surface 9. In FIG. 13, hatched regions indicate the plurality of outer circumferential regions 60.

The plurality of central regions 70 are surrounded by the plurality of outer circumferential regions 60. Each of the plurality of central regions 70 is spaced from the square regions intersecting outer circumferential side surface 9.

As shown in FIG. 5, when diameter D of first main surface 1 is 150 mm, first main surface 1 is divided into 145 square regions 50 each having a side length (first length W1) of 10 mm. The LTIR is measured in each of 145 square regions 50. When diameter D of first main surface 1 is 150 mm, the number of outer circumferential regions 60 is 68, and the number of central regions 70 is 77. Of the plurality of outer circumferential regions 60, the number of first outer circumferential regions 61 is 36, and the number of second outer circumferential regions 62 is 32.

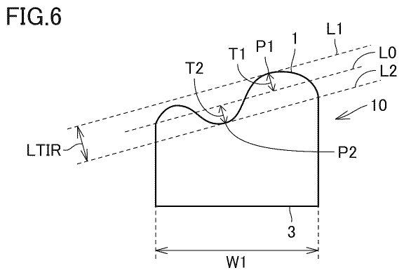

Next, the definition of the LTIR is described. FIG. 6 is a schematic diagram illustrating the definition of the LTIR.

$$LTIR = \vert T 1 \vert + \vert T 2 \vert \qquad ( Equation 1 )$$

The LTIR is measured by the following procedure, for example. Silicon carbide substrate 10 in the state before the formation of silicon carbide epitaxial layer 20 is prepared. Third main surface 3 of silicon carbide substrate 10 is entirely adsorbed to a flat adsorption surface. Then, an image of first main surface 1 in a certain local region (such as central regions 70 and outer circumferential regions 60) is optically acquired. Then, a least square plane L0 of first main surface 1 is calculated and determined.

As shown in Equation 1 and FIG. 6, the LTIR is a value determined by adding a height (first highest point height T1) from least square plane L0 to the highest point (first highest point P1) of first main surface 1 and a height (first lowest point height T2) from least square plane L0 to the lowest point (first lowest point P2) of first main surface 1, while keeping third main surface 3 entirely adsorbed to the flat adsorption surface. First highest point P1 is a position where the distance between least square plane L0 and first main surface 1 along a direction perpendicular to least square plane L0 is at its maximum in a region of first main surface 1 that is located opposite to third main surface 3 with respect to least square plane L0. First lowest point P2 is a position where the distance between least square plane L0 and first main surface 1 along the direction perpendicular to least square plane L0 is at its maximum in a region of first main surface 1 that is located on the third main surface 3 side with respect to least square plane L0. That is, the LTIR is a distance between a plane (first highest point plane L1) passing through first highest point P1 and parallel to least square plane L0 and a plane (first lowest point plane L2) passing through first lowest point P2 and parallel to least square plane L0.

Since silicon carbide epitaxial layer 20 has a thickness that is substantially in-plane uniform, silicon carbide substrate 10 and silicon carbide epitaxial substrate 100 have substantially the same LTIR. In other words, the LTIR of silicon carbide epitaxial substrate 100 may be measured instead of the LTIR of silicon carbide substrate 10. In measuring the LTIR of silicon carbide epitaxial substrate 100, second main surface 2 is subjected to the above-described procedure after third main surface 3 has been entirely adsorbed.

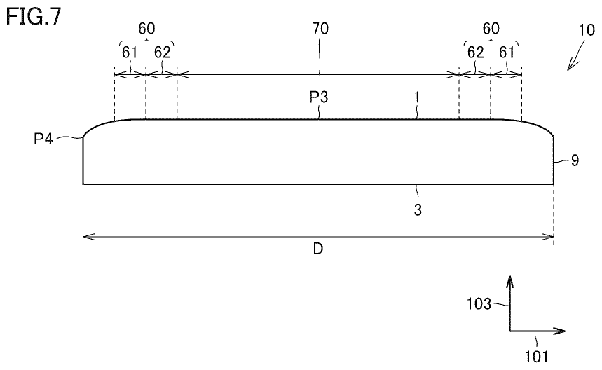

FIG. 7 is a schematic cross-sectional view along a line VII-VII in FIG. 5. The cross section shown in FIG. 7 is perpendicular to first main surface 1, and parallel to first direction 101. As shown in FIG. 7, first main surface 1 approaches third main surface 3 toward outer circumferential side surface 9 as seen in the cross-sectional view. From a different viewpoint, first outer circumferential region 61 is located between third main surface 3 and second outer circumferential region 62 in third direction 103.

Central region 70 may be linear as seen in the cross-sectional view. Outer circumferential region 60 is curved, for example, as seen in the cross-sectional view. From a different viewpoint, an average value of the LTIR of silicon carbide substrate 10 in the plurality of outer circumferential regions 60 is greater than an average value of the LTIR of silicon carbide substrate 10 in the plurality of central regions 70.

Second outer circumferential region 62 is curved, for example, as seen in the cross-sectional view. First outer circumferential region 61 is curved, for example, as seen in the cross-sectional view. First outer circumferential region 61 has a greater curvature than second outer circumferential region 62 as seen in the cross-sectional view. From a different viewpoint, an average value of the LTIR of silicon carbide substrate 10 in the plurality of first outer circumferential regions 61 is greater than an average value of the LTIR of silicon carbide substrate 10 in the plurality of second outer circumferential regions 62.

The average value of the LTIR of silicon carbide substrate 10 in the plurality of outer circumferential regions 60 is 0.6 μm or less, for example. The LTIR of silicon carbide substrate 10 in the plurality of outer circumferential regions 60 is not particularly limited, and may be 0.4 μm or less, or 0.25 μm or less, for example. The LTIR of silicon carbide substrate 10 in the plurality of outer circumferential regions 60 is not particularly limited, and may be 0.01 μm or more, 0.03 μm or more, or 0.05 μm or more, for example.

### (Total Thickness Variation of Silicon Carbide Substrate)

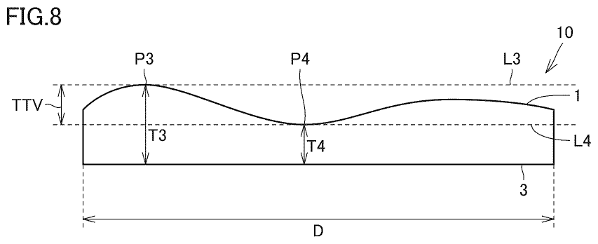

Next, the total thickness variation (TTV) is described. FIG. 8 is a schematic cross-sectional view illustrating the definition of the total thickness variation.

$$TTV = \vert T 3 - T 4 \vert \qquad ( Equation 2 )$$

The TTV is measured by the following procedure, for example. First, silicon carbide substrate 10 in the state before the formation of silicon carbide epitaxial layer 20 is prepared. Third main surface 3 of silicon carbide substrate 10 is entirely adsorbed to a flat adsorption surface. Then, an entire image of first main surface 1 is optically acquired. As shown in FIG. 8 and Equation 2, the TTV is a value determined by subtracting a height (second lowest point height T4) from third main surface 3 to the lowest point (second lowest point P4) of first main surface 1 from a height (second highest point height T3) from third main surface 3 to the highest point (second highest point P3) of first main surface 1, while keeping third main surface 3 entirely adsorbed to the flat adsorption surface. In other words, the TTV is a value determined by subtracting the shortest distance between first main surface 1 and third main surface 3 from the longest distance between first main surface 1 and third main surface 3 in a direction perpendicular to third main surface 3. That is, the TTV is a distance between a plane (second highest point plane L3) passing through second highest point P3 and parallel to third main surface 3 and a plane (second lowest point plane L4) passing through second lowest point P4 and parallel to third main surface 3.

Since silicon carbide epitaxial layer 20 has a thickness that is substantially in-plane uniform, silicon carbide substrate 10 and silicon carbide epitaxial substrate 100 have substantially the same TTV. In other words, the TTV of silicon carbide epitaxial substrate 100 may be measured instead of the TTV of silicon carbide substrate 10. In measuring the TTV of silicon carbide epitaxial substrate 100, second main surface 2 is subjected to the above-described procedure after third main surface 3 has been entirely adsorbed.

The TTV of silicon carbide substrate 10 according to the present embodiment is 6 μm or less, for example. The TTV is not particularly limited, and may be 4 μm or less, or 2 μm or less, for example. The TTV is not particularly limited, and may be 0.1 μm or more, or 0.5 μm or more, for example.

As shown in FIG. 7, in silicon carbide substrate 10, second lowest point P4 is located on a ridge of first main surface 1 and outer circumferential side surface 9, for example. Second highest point P3 is located in central region 70, for example.

### (Electrical Resistivity of Silicon Carbide Substrate)

Silicon carbide substrate 10 has an electrical resistivity of 10 mΩ·cm or more, for example. The electrical resistivity of silicon carbide substrate 10 is not particularly limited, and may be 15 mΩ·cm or more, or 18 mΩ·cm or more, for example. The electrical resistivity of silicon carbide substrate 10 is not particularly limited, and is 25 mΩ·cm or less, for example. The electrical resistivity of silicon carbide substrate 10 can be measured using an electrical resistivity measuring device “EC-80” manufactured by Napson Corporation, for example. Specifically, the electrical resistivity of silicon carbide substrate 10 is measured after silicon carbide epitaxial layer 20 has been removed.

### (Method for Manufacturing Silicon Carbide Epitaxial Substrate)

Next, a method for manufacturing silicon carbide epitaxial substrate 100 is described.

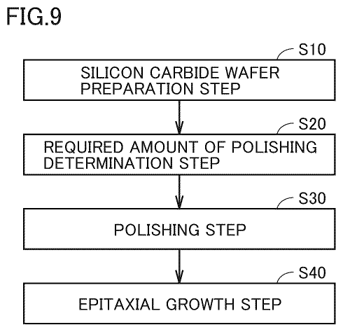

FIG. 9 is a flow chart schematically showing the method for manufacturing the silicon carbide epitaxial substrate according to the present embodiment. As shown in FIG. 9, the method for manufacturing the silicon carbide epitaxial substrate according to the present embodiment mainly includes a silicon carbide wafer preparation step (S10), a required amount of polishing determination step (S20), a polishing step (S30), and an epitaxial growth step (S40).

First, the silicon carbide wafer preparation step (S10) is performed. A silicon carbide crystal having a polytype of 4H is produced by a sublimation method, for example. Then, the silicon carbide crystal is sliced with a wire saw, for example, into a plurality of silicon carbide wafers 90. Each of the plurality of silicon carbide wafers 90 has substantially the same configuration.

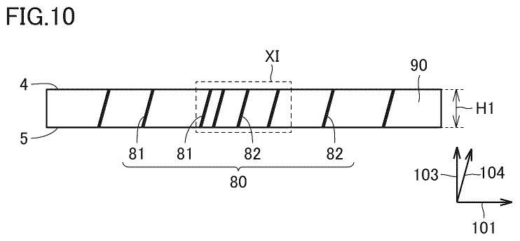

FIG. 10 is a schematic cross-sectional view showing the configuration of silicon carbide wafer 90. As shown in FIG. 10, silicon carbide wafer 90 has a fourth main surface 4 and a fifth main surface 5. Fifth main surface 5 is located opposite to fourth main surface 4. Silicon carbide wafer 90 has a plurality of threading dislocations 80. Threading dislocations 80 continuously extend from fourth main surface 4 to fifth main surface 5. Threading dislocations 80 are exposed at fourth main surface 4. Threading dislocations 80 are exposed at fifth main surface 5. The cross section shown in FIG. 10 is a cross section parallel to each of first direction 101 and third direction 103 and through fourth main surface 4.

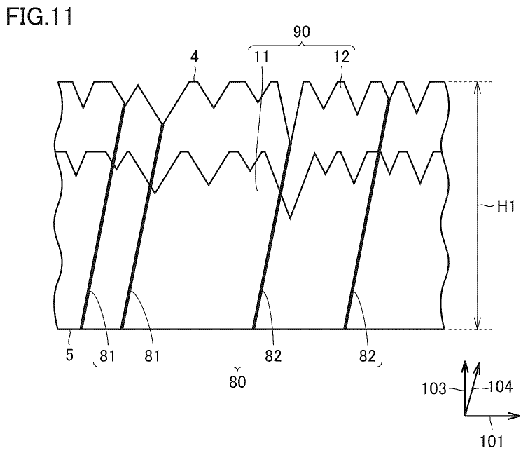

FIG. 11 is a schematic enlarged view showing a region XI in FIG. 10. As shown in FIG. 11, silicon carbide wafer 90 is formed by normal portion 11 and damaged portion 12. Damaged portion 12 covers normal portion 11. Damaged portion 12 forms fourth main surface 4. As shown in FIG. 11, fourth main surface 4 is a plane which has been formed by slicing with a wire saw and not been subsequently polished. Fifth main surface 5 may be a plane which has been smoothed by polishing. The thickness of silicon carbide wafer 90 is referred to as a first thickness H1. Silicon carbide wafer 90 is prepared as described above.

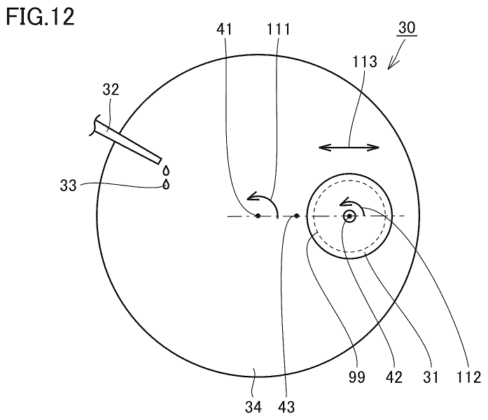

Next, a configuration of a polishing apparatus is described. FIG. 12 is a schematic plan view showing the configuration of the polishing apparatus. FIG. 13 is a schematic front view showing the configuration of the polishing apparatus. A polishing apparatus 30 is a mechanical polishing apparatus, for example.

As shown in FIGS. 12 and 13, polishing apparatus 30 mainly includes a polishing head 31, an abrasive supply unit 32, a polishing cloth 34, and a surface plate 35. Polishing head 31 includes a support plate 37, a weight 38, and a post 39. Weight 38 is positioned on support plate 37. Post 39 is positioned on weight 38. Polishing cloth 34 is secured to surface plate 35. The “KV” series manufactured by Poval Kogyo Co., Ltd., can be used, for example, as polishing cloth 34. Polishing cloth 34 may be a nonwoven cloth, for example. Polishing cloth 34 may have a stacking structure. A stacking direction of polishing cloth 34 is a direction perpendicular to a vertical direction, for example. The vertical direction is a direction from polishing cloth 34 toward polishing head 31.

Next, the required amount of polishing determination step (S20) is performed. One silicon carbide wafer 90 of the plurality of silicon carbide wafers 90 is prepared as a dummy wafer 99. Dummy wafer 99 is a wafer different from silicon carbide wafer 90 which is polished in the next polishing step (S30).

As shown in FIGS. 12 and 13, dummy wafer 99 is attached to support plate 37 of polishing head 31. An abrasive 33 is supplied onto polishing cloth 34. In abrasive 33, polycrystalline diamond is used, for example, as abrasive grains. The abrasive grains of abrasive 33 each have a grain diameter (D₉₀) of 0.2 μm or more and 1.5 μm or less, for example. The grain diameter (D₉₀) means a grain diameter corresponding to a cumulative value of 90% in a grain diameter distribution of the abrasive grains. In abrasive 33, oil is used, for example, as a lubricant. Abrasive 33 is supplied in an amount of 5 cm³/min or more and 50 cm³/min or less, for example.

Polishing head 31 and polishing cloth 34 rotate while fourth main surface 4 of dummy wafer 99 is pressed against polishing cloth 34 by polishing head 31. Dummy wafer 99 is pressurized with a dead-weight method. Specifically, polishing head 31 presses dummy wafer 99 against polishing cloth 34 using the mass of weight 38. In other words, post 39 does not have a role to actively pressurize dummy wafer 99. This can allow dummy wafer 99 to oscillate in the vertical direction during polishing, as compared to when dummy wafer 99 is pressurized by an air cylinder or the like. Accordingly, friction resistance acting on fourth main surface 4 of dummy wafer 99 locally varies. Dummy wafer 99 is pressed against polishing cloth 34 at a pressure of 250 g/cm², for example.

As shown in FIG. 12, surface plate 35 with polishing cloth 34 secured thereto rotates on its own axis. Specifically, surface plate 35 with polishing cloth 34 secured thereto rotates around a first rotation axis 41 in a first rotation direction 111. First rotation axis 41 passes through the center of polishing cloth 34, for example. Surface plate 35 has a rotation speed of 40 rpm or more and 100 rpm or less, for example. First rotation direction 111 is counterclockwise, for example, as seen from above polishing cloth 34.

As shown in FIG. 12, polishing head 31 rotates on its own axis. Specifically, polishing head 31 rotates around a second rotation axis 42 in a second rotation direction 112. Second rotation axis 42 passes through the center of polishing head 31, for example. Polishing head 31 has a rotation speed of 80 rpm or more and 120 rpm or less, for example. Second rotation direction 112 is counterclockwise, for example, as seen from above polishing cloth 34.

As shown in FIG. 12, polishing head 31 swings in a swing direction 113 while rotating on its own axis. Swing direction 113 is a direction from first rotation axis 41 toward second rotation axis 42, for example, as seen from above polishing cloth 34. In other words, swing direction 113 is a radial direction of polishing cloth 34, for example. Polishing head 31 swings within polishing cloth 34 as seen from above polishing cloth 34. Polishing head 31 has a swing width that is 0.5 times or more and 0.8 times or less the diameter of dummy wafer 99, for example. Polishing head 31 has a swing speed of 10 mm/sec or more and 30 mm/sec or less, for example.

As shown in FIG. 12, when dummy wafer 99 is closest to first rotation axis 41, a point closest to first rotation axis 41 of points on the outer circumference of dummy wafer 99 is a center-side swing end 43. A circumferential velocity of surface plate 35 at center-side swing end 43 is twice or more the circumferential velocity of dummy wafer 99 at center-side swing end 43. The circumferential velocity of dummy wafer 99 at center-side swing end 43 is equal to a circumferential velocity of dummy wafer 99 at the outer circumference of dummy wafer 99.

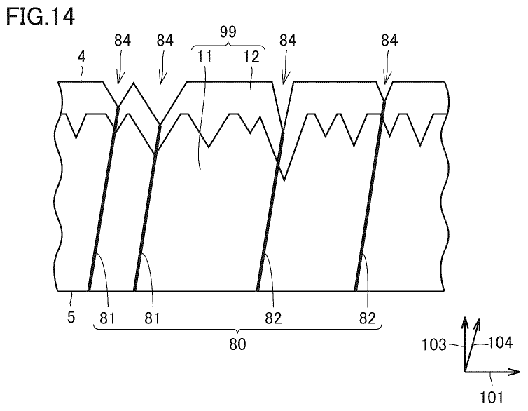

FIG. 14 is a schematic enlarged cross-sectional view showing a configuration of dummy wafer 99 during the required amount of polishing determination step (S20). The schematic enlarged view shown in FIG. 14 corresponds to the schematic enlarged view shown in FIG. 11.

In the required amount of polishing determination step (S20), polishing is performed such that friction force acting on fourth main surface 4 of dummy wafer 99 locally varies. Accordingly, an easily shaved portion of fourth main surface 4 is significantly shaved like a spike, as compared to other portions of fourth main surface 4. Specifically, as shown in FIG. 14, a portion of fourth main surface 4 that is in the vicinity of threading dislocation 80 and that is damaged portion 12 is significantly shaved like a spike, as compared to other portions of fourth main surface 4. A void 84 is thereby formed in fourth main surface 4. From a different viewpoint, during the required amount of polishing determination step (S20), void 84 is provided in the vicinity of threading dislocation 80, and void 84 is provided in damaged portion 12. Void 84 has a depth of 10 μm or more and 200 μm or less, for example, in third direction 103. Fourth main surface 4 except for void 84 is polished to be smooth.

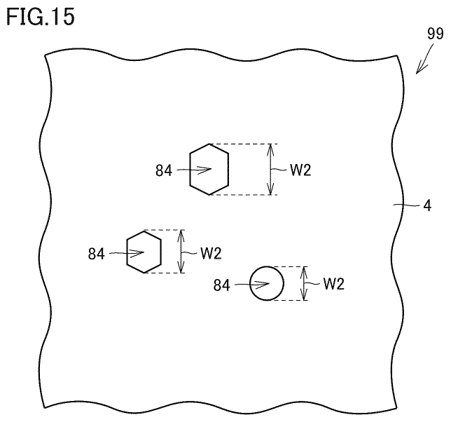

FIG. 15 is a schematic enlarged plan view showing the configuration of dummy wafer 99 during the required amount of polishing determination step. As shown in FIG. 15, void 84 may be hexagonal as seen in a direction perpendicular to fourth main surface 4. Void 84 may be circular as seen in the direction perpendicular to fourth main surface 4. When void 84 is hexagonal as seen in the direction perpendicular to fourth main surface 4, the length of void 84 (second length W2) is the longitudinal length of void 84 as seen in the direction perpendicular to fourth main surface 4. When void 84 is circular as seen in the direction perpendicular to fourth main surface 4, second length W2 of void 84 is the diameter of void 84. Second length W2 is 10 μm or more and 100 μm or less, for example.

In the required amount of polishing determination step (S20), after dummy wafer 99 has been polished by a predetermined amount of polishing, an area density of voids 84 in fourth main surface 4 of dummy wafer 99 is measured.

Void 84 can be identified by, for example, an optical microscope, a laser microscope, or a defect inspection device such as “SICA 6X” of the WASAVI series manufactured by Lasertec Corporation. Specifically, fourth main surface 4 is observed using an optical microscope, for example. An objective lens has a magnification of 5×, for example. The optical microscope has a field of view of a 3 mm square, for example. Of the holes detected by the observation, each one having a longitudinal length of 10 μm or more and 100 μm or less is identified as void 84. The area density of voids 84 in fourth main surface 4 is measured by dividing the number of voids 84 in fourth main surface 4 by the area of fourth main surface 4.

In the required amount of polishing determination step (S20), the polishing and the measuring of the area density of voids 84 are repeated. In the required amount of polishing determination step (S20), a threshold value for the area density of voids 84 (hereinafter also referred to as an area density threshold value) is set. When a measurement of the area density of voids 84 is less than the area density threshold value, the amount of polishing performed in the required amount of polishing determination step (S20) is measured. The area density threshold value is 0.3/cm², for example. The area density threshold value may be 0.3/cm² or less, for example.

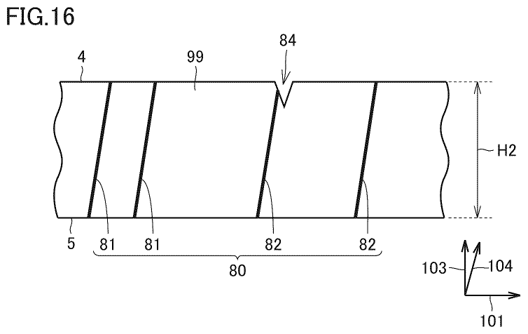

FIG. 16 is a schematic enlarged view showing the configuration of the dummy wafer after the required amount of polishing determination step. The schematic enlarged view shown in FIG. 16 corresponds to the schematic enlarged view shown in FIG. 11. A value determined by subtracting a thickness (second thickness H2) of dummy wafer 99 after the required amount of polishing determination step (S20) from first thickness H1 of silicon carbide wafer 90 in the silicon carbide wafer preparation step (S10) is measured as the amount of polishing performed in the required amount of polishing determination step (S20). The measured amount of polishing is determined as a required amount of polishing.

As shown in FIG. 16, normal portion 11 is exposed after the required amount of polishing determination step (S20). In other words, damaged portion 12 of dummy wafer 99 is removed after the required amount of polishing determination step (S20).

Next, the polishing step (S30) is performed. Silicon carbide wafer 90 is first prepared. Silicon carbide wafer 90 has a similar configuration to dummy wafer 99. Silicon carbide wafer 90 is polished by mechanical polishing. The amount of polishing of silicon carbide wafer 90 by the mechanical polishing is the required amount of polishing determined in the required amount of polishing determination step (S20), for example. The amount of polishing of silicon carbide wafer 90 by the mechanical polishing may be more than or equal to the required amount of polishing. When the amount of polishing of silicon carbide wafer 90 by the mechanical polishing is excessively large, however, the time required for the mechanical polishing increases, and the area density of polishing marks in fourth main surface 4 of silicon carbide wafer 90 increases. Accordingly, the amount of polishing of silicon carbide wafer 90 by the mechanical polishing is preferably the required amount of polishing.

A mechanical polishing apparatus used for the mechanical polishing has a different configuration from polishing apparatus 30 in that post 39 has a role to actively pressurize silicon carbide wafer 90, and otherwise has a similar configuration to polishing apparatus 30. Specifically, post 39 of the mechanical polishing apparatus has an air cylinder, for example. The polishing conditions for the mechanical polishing are similar to the polishing conditions in the required amount of polishing determination step (S20).

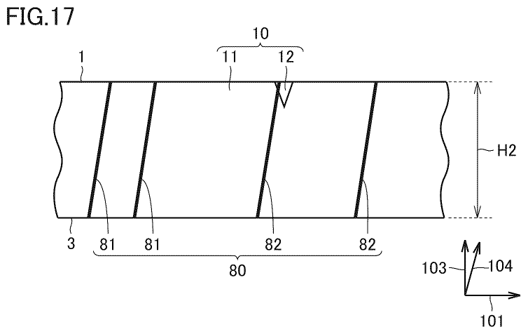

FIG. 17 is a schematic enlarged view showing a configuration of silicon carbide substrate 10 in the polishing step (S30). The schematic enlarged view shown in FIG. 17 corresponds to the schematic enlarged view shown in FIG. 11. As shown in FIG. 17, first main surface 1 of silicon carbide substrate 10 is smooth. The position of damaged portion 12 in silicon carbide substrate 10 corresponds to the position of void 84 in dummy wafer 99 after the required amount of polishing determination step (S20) (see FIG. 16). The thickness of silicon carbide substrate 10 is second thickness H2.

Then, silicon carbide wafer 90 is subjected to chemical mechanical polishing (CMP). The amount of polishing by the CMP is 3 μm, for example. A CMP apparatus used for the CMP has a different configuration from polishing apparatus 30 in that post 39 has a role to actively pressurize silicon carbide wafer 90, and otherwise has a similar configuration to polishing apparatus 30. Specifically, post 39 of the CMP apparatus has an air cylinder, for example.

In an abrasive used for the CMP, colloidal silica “PL-3H” produced by Fuso Chemical Co., Ltd. is used, for example, as abrasive grains. Sodium dichloroisocyanurate is used, for example, as an oxidizer. Sucrose is used, for example, as an additive. In the abrasive used for the CMP, 1000 cm³ of the colloidal silica, 50 g of the oxidizer, and 40 g of the additive are added to 4000 cm³ of water, for example. The amount of each of the water, the colloidal silica, the oxidizer and the additive may be changed while the ratio of these amounts is maintained. The abrasive used for the CMP has a hydrogen ion exponent (pH) of 2.5 or more and 3.5 or less, for example.

In the CMP apparatus, a polyurethane suede polishing cloth “Supreme™” manufactured by Nitta DuPont Incorporated is used, for example, as a polishing cloth. A surface plate has a diameter of 640 mm, for example. The surface plate has a rotation speed of 60 rpm, for example. A polishing head has a rotation speed of 80 rpm, for example. The polishing head has a swing speed of 20 mm/sec, for example. The abrasive has a flow rate of 200 cm³/min, for example. Silicon carbide substrate 10 is fabricated as described above.

Next, the epitaxial growth step (S40) is performed. Silicon carbide epitaxial layer 20 is formed on first main surface 1 of silicon carbide substrate 10. Of the plurality of threading dislocations 80, those in damaged portion 12 of silicon carbide substrate 10 are converted to form blue light-emitting defects 83. Silicon carbide epitaxial substrate 100 (see FIG. 3) is fabricated as described above.

Silicon carbide epitaxial substrate 100 is used as a substrate of a silicon carbide semiconductor device such as a metal oxide semiconductor field effect transistor (MOSFET).

Next, functions and advantageous effects of silicon carbide epitaxial substrate 100 according to the present embodiment are described.

When a silicon carbide semiconductor device is fabricated using silicon carbide epitaxial substrate 100, electrical characteristics of the silicon carbide semiconductor device deteriorate by the defects exposed at second main surface 2 of silicon carbide epitaxial substrate 100. This results in reduced yield of the silicon carbide semiconductor device. A detailed study of the cause of this phenomenon by the inventors found that blue light-emitting defects 83 exposed at second main surface 2 particularly affected the deterioration of the electrical characteristics of the silicon carbide semiconductor device.

The inventors also made the following findings by studying the factors responsible for the formation of blue light-emitting defects 83. Specifically, blue light-emitting defects 83 are formed due to threading dislocations 80 in damaged portion 12 of silicon carbide substrate 10. From a different viewpoint, the ratio of conversion from threading dislocations 80 to blue light-emitting defects 83 varies with the amount of damaged portion 12 remaining in silicon carbide substrate 10.

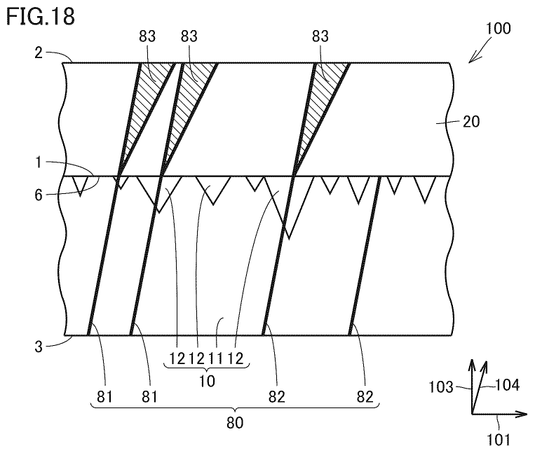

In determining the amount of polishing of silicon carbide substrate 10, surface roughness of silicon carbide substrate 10 may be used as an indicator. Polishing of silicon carbide substrate 10 and measuring of the surface roughness are repeated, and silicon carbide substrate 10 is polished until the surface roughness of silicon carbide substrate 10 becomes less than or equal to a predetermined value. When the polishing was performed so as to obtain a sufficiently low surface roughness of first main surface 1 of silicon carbide substrate 10, however, damaged portion 12 was sometimes not sufficiently removed. FIG. 18 is a schematic enlarged cross-sectional view showing a state in which silicon carbide epitaxial layer 20 is formed after the polishing has been performed so as to obtain a sufficiently low surface roughness of first main surface 1 of silicon carbide substrate 10. The schematic enlarged cross-sectional view shown in FIG. 18 corresponds to the schematic enlarged cross-sectional view shown in FIG. 3.

Damaged portion 12 is locally formed deep into silicon carbide wafer 90 (see FIG. 11). As shown in FIG. 18, therefore, when the polishing is performed so as to obtain a sufficiently low surface roughness of first main surface 1 of silicon carbide substrate 10, only a surface layer of damaged portion 12 is removed, and a part of damaged portion 12 formed deep into silicon carbide wafer 90 is not removed. From a different viewpoint, when the polishing is performed so as to obtain a sufficiently low surface roughness of first main surface 1, the amount of polishing is excessively small. Accordingly, the amount of remaining damaged portion 12 increases. In this case, the number of threading dislocations 80 in damaged portion 12 increases. As a result, the ratio of conversion from threading dislocations 80 to blue light-emitting defects 83 increases.

At normal temperature, damaged portion 12 formed deep into silicon carbide wafer 90 does not affect a warp of silicon carbide wafer 90. Accordingly, even when the polishing is performed so as to obtain a sufficiently small warp of silicon carbide substrate 10, damaged portion 12 formed deep into silicon carbide wafer 90 is not removed. Therefore, the amount of polishing is excessively small, as when the polishing is performed so as to obtain a sufficiently low surface roughness of silicon carbide substrate 10.

When the amount of polishing by the mechanical polishing is excessively increased, on the other hand, more polishing marks are formed on first main surface 1 of silicon carbide substrate 10 after the mechanical polishing. Accordingly, it is required to increase the amount of polishing by the CMP in order to reduce the area density of polishing marks in first main surface 1.

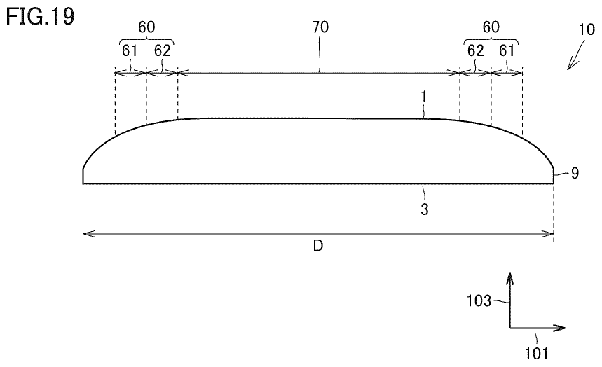

FIG. 19 is a schematic cross-sectional view showing a state in which the amount of polishing by mechanical polishing in the polishing step is excessively large. The schematic cross-sectional view shown in FIG. 19 corresponds to the schematic cross-sectional view shown in FIG. 7. As shown in FIG. 19, when the amount of polishing by the CMP is increased, the degree of sag of the outer circumferential portion of first main surface 1 increases because the outer circumferential portion is more likely to come into contact with the polishing solution than the inner circumferential portion. Specifically, first outer circumferential region 61 and second outer circumferential region 62 each have an increased curvature as seen in the cross-sectional view. Central region 70 is curved as seen in the cross-sectional view. From a different viewpoint, the LTIR of silicon carbide substrate 10 in the plurality of outer circumferential regions 60 increases. This causes deterioration in flatness of silicon carbide epitaxial substrate 100, and increase in pattern defects of a silicon carbide semiconductor device fabricated using silicon carbide epitaxial substrate 100. This results in reduced yield of a silicon carbide semiconductor device fabricated using silicon carbide epitaxial substrate 100.

As described above, when the amount of polishing is excessively small, the amount of remaining damaged portion 12 increases, and therefore, the ratio of conversion from threading dislocations 80 to blue light-emitting defects 83 increases. When the amount of polishing is excessively large, on the other hand, the amount of polishing by the CMP increases, and therefore, the LTIR of silicon carbide substrate 10 in the plurality of outer circumferential regions 60 increases. Accordingly, it is required to determine an optimal amount of polishing in order to reduce the area density of the blue light-emitting defects and to reduce the LTIR.

The inventors made the following findings after conducting an elaborate study of how to determine the amount of polishing, and determined to introduce the required amount of polishing determination step (S20) in the method for manufacturing silicon carbide epitaxial substrate 100 according to the present application. Damaged portion 12 in the vicinity of threading dislocation 80 is more easily shaved than each of other damaged portions 12 and normal portion 11. In the required amount of polishing determination step (S20), therefore, damaged portion 12 in the vicinity of threading dislocation 80 is shaved deeply by performing the polishing such that the friction resistance locally varies. As a result, damaged portion 12 in the vicinity of threading dislocation 80 is detected as void 84.

Accordingly, the amount of remaining damaged portion 12 can be reduced by calculating the amount of polishing required for the area density of voids 84 to become less than or equal to a predetermined number, and performing the polishing such that the amount of polishing in the polishing step (S30) becomes equal to the required amount of polishing. The ratio of conversion from threading dislocations 80 to blue light-emitting defects 83 can thereby be reduced. From a different viewpoint, the thickness of damaged portion 12 in third direction 103 can be reduced, as compared to when the amount of polishing is excessively small (see FIGS. 3 and 18). In addition, excessive increase in the amount of polishing by the mechanical polishing in the polishing step (S30) can be suppressed, and therefore, the amount of polishing by the CMP can be reduced. Accordingly, excessive increase in the LTIR of silicon carbide substrate 10 in outer circumferential regions 60 can be suppressed.

In silicon carbide epitaxial substrate 100 according to the present embodiment, when the area density of threading screw dislocations 81 in first main surface 1 of silicon carbide substrate 10 is the first area density, the area density of threading edge dislocations 82 in first main surface 1 is the second area density, and the area density of blue light-emitting defects 83 in second main surface 2 is the third area density, the ratio of the third area density to the sum of the first area density and the second area density is 0.03% or less. Accordingly, the area density of blue light-emitting defects 83 in second main surface 2 of silicon carbide epitaxial substrate 100 is reduced. Thus, the yield of a silicon carbide semiconductor device fabricated using silicon carbide epitaxial substrate 100 can be improved.

In silicon carbide epitaxial substrate 100 according to the present embodiment, when first main surface 1 of silicon carbide substrate 10 is divided into the plurality of square regions 50 each having a side length of 10 mm, the plurality of square regions 50 include the plurality of first outer circumferential regions 61 located at the outermost circumference of the plurality of square regions 50, and the plurality of second outer circumferential regions 62 in contact with the plurality of first outer circumferential regions 61. The average value of the LTIR of silicon carbide substrate 10 in the plurality of first outer circumferential regions 61 and the plurality of second outer circumferential regions 62 is 0.6 μm or less. Accordingly, the flatness of outer circumferential regions 60 of first main surface 1 is improved. Thus, the yield of a silicon carbide semiconductor device fabricated using silicon carbide epitaxial substrate 100 can be improved.

In silicon carbide epitaxial substrate 100 according to the present embodiment, silicon carbide substrate 10 has a total thickness variation of 6 μm or less. Accordingly, the flatness of first main surface 1 is improved. Thus, the yield of a silicon carbide semiconductor device fabricated using silicon carbide epitaxial substrate 100 can be improved.

In silicon carbide epitaxial substrate 100 according to the present embodiment, the ratio of the third area density to the sum of the first area density and the second area density may be 0.02% or less. Thus, the yield of a silicon carbide semiconductor device fabricated using silicon carbide epitaxial substrate 100 can be further improved.

In silicon carbide epitaxial substrate 100 according to the present embodiment, the ratio of the third area density to the sum of the first area density and the second area density may be 0.01% or less. Thus, the yield of a silicon carbide semiconductor device fabricated using silicon carbide epitaxial substrate 100 can be further improved.

In silicon carbide epitaxial substrate 100 according to the present embodiment, the ratio of the third area density to the first area density is 0.2% or less. Thus, the yield of a silicon carbide semiconductor device fabricated using silicon carbide epitaxial substrate 100 can be further improved.

In silicon carbide epitaxial substrate 100 according to the present embodiment, the first area density is 1500/cm² or less. Accordingly, the area density of threading screw dislocations 81 in first main surface 1 is reduced. Thus, the area density of blue light-emitting defects 83 in second main surface 2 can be further reduced.

In silicon carbide epitaxial substrate 100 according to the present embodiment, the first area density is 500/cm² or less. Accordingly, the area density of threading screw dislocations 81 in first main surface 1 is reduced. Thus, the area density of blue light-emitting defects 83 in second main surface 2 can be further reduced.

In silicon carbide epitaxial substrate 100 according to the present embodiment, the first area density is 100/cm² or less. Accordingly, the area density of threading screw dislocations 81 in first main surface 1 is reduced. Thus, the area density of blue light-emitting defects 83 in second main surface 2 can be further reduced.

In silicon carbide epitaxial substrate 100 according to the present embodiment, the second area density is 10000/cm² or less. Accordingly, the area density of threading edge dislocations 82 in first main surface 1 is reduced. Thus, the area density of blue light-emitting defects 83 in second main surface 2 can be further reduced.

In silicon carbide epitaxial substrate 100 according to the present embodiment, the second area density is 5000/cm² or less. Accordingly, the area density of threading edge dislocations 82 in first main surface 1 is reduced. Thus, the area density of blue light-emitting defects 83 in second main surface 2 can be further reduced.

In silicon carbide epitaxial substrate 100 according to the present embodiment, the second area density is 2000/cm² or less. Accordingly, the area density of threading edge dislocations 82 in first main surface 1 is reduced. Thus, the area density of blue light-emitting defects 83 in second main surface 2 can be further reduced.

In silicon carbide epitaxial substrate 100 according to the present embodiment, second main surface 2 has diameter D of 150 mm or more. In this manner, even with silicon carbide epitaxial substrate 100 having a large diameter, the yield of a silicon carbide semiconductor device fabricated using silicon carbide epitaxial substrate 100 can be improved.

### Examples

### (Sample Preparation)

Tests with samples are now described. Silicon carbide epitaxial substrates 100 according to sample 1 to sample 7 were first prepared. Each of sample 1 and sample 4 is a comparative example. Each of sample 2, sample 3, and sample 5 to sample 7 is an example.

Each of silicon carbide epitaxial substrates 100 according to sample 1 to sample 7 was fabricated using the manufacturing method according to the present embodiment described above. Surface plate 35 had a rotation speed of 40 rpm or more and 100 rpm or less in the required amount of polishing determination step (S20). The polishing head had a rotation speed of 80 rpm or more and 120 rpm or less. Polishing head 31 had a swing speed of 10 mm/sec or more and 30 mm/sec or less. The conditions for the mechanical polishing in the polishing step (S30) were similar to the polishing conditions in the required amount of polishing determination step (S20).

As shown in Table 1, sample 1 to sample 4 were prepared to have similar area densities of threading screw dislocations 81 (TSDs) in first main surface 1 (first area densities) and similar area densities of threading edge dislocations 82 (TEDs) in first main surface 1 (second area densities). Specifically, the first area densities of silicon carbide epitaxial substrates 100 according to sample 1 to sample 4 were 470/cm², 500/cm², 540/cm², and 520/cm², respectively. The second area densities of silicon carbide epitaxial substrates 100 according to sample 1 to sample 4 were 3250/cm², 4000/cm², 3500/cm², and 4100/cm².

Sample 5 to sample 7 were prepared to have different first area densities and different second area densities. Specifically, the first area densities of silicon carbide epitaxial substrates 100 according to sample 5 to sample 7 were 1340/cm², 870/cm², and 200/cm². The second area densities of silicon carbide epitaxial substrates 100 according to sample 5 to sample 7 were 9060/cm², 5620/cm², and 1870/cm².

In fabricating silicon carbide epitaxial substrates 100 according to sample 1 to sample 7, the threshold value for the area density of voids in the required amount of polishing determination step (S20) was varied. This resulted in varied area densities of voids after the required amount of polishing determination step (S20), as shown in Table 1. Specifically, in sample 1 to sample 3, the area density of voids varied between 0.05/cm² or more and 0.6/cm² or less. In sample 4, the threshold value for the area density of voids was set so as to obtain a similar area density of voids to sample 2. In sample 5 to sample 7, the area density of voids varied between 0.03/cm² or more and 0.19/cm² or less. In each of sample 1 to sample 7, the required amount of polishing was determined based on the set threshold value for the area density of voids.

As shown in Table 1, in sample 1 to sample 4, since they have similar first area densities and similar second area densities, the determined amounts of polishing also varied due to the varied threshold values for the area density of voids. In sample 5 to sample 7, since they have different first area densities and different second area densities, the determined amounts of polishing were equal despite the varied threshold values for the area density of voids.

As shown in Table 1, in sample 1 to sample 3 and sample 5 to sample 7, the amount of polishing by the CMP in the polishing step (S30) was 3 μm. In sample 4, the amount of polishing by the CMP in the polishing step (S30) was 8 μm.

### (Measurement Method)

In all of the samples, each of the first area density and the second area density was measured using the measurement method described above. In measuring each of the first area density and the second area density, first main surface 1 was observed using a Nomarski differential interference microscope. The observed field of view of etch pits was 0.082 cm×0.070 cm. First main surface 1 of silicon carbide substrate 10 was divided into a plurality of square measurement regions. Each of the plurality of square measurement regions had a size of 5 mm×5 mm. The number of etch pits was determined in each of the plurality of square measurement regions. A value determined by dividing the number of etch pits in a square measurement region by the area of the observed field of view of etch pits (0.082 cm×0.070 cm) was determined as the area density of threading screw dislocations 81 in this square measurement region.

A value determined by dividing the sum of the area densities of threading screw dislocations 81 in all of the square measurement regions by the number of the square measurement regions was determined as the area density of threading screw dislocations 81 in first main surface 1 of silicon carbide substrate 10 (first area density). Similarly, the area density of threading edge dislocations 82 in first main surface 1 of silicon carbide substrate 10 (second area density) was measured.

In all of the samples, the total thickness variation (TTV) of the silicon carbide substrate was measured. Specifically, the TTV was measured by the measurement method described above, using a flatness measuring machine “Tropel FlatMaster™” manufactured by Corning Tropel Corporation.

In all of the samples, an average value of the LTIR of the silicon carbide substrate in outer circumferential regions 60 was measured. Specifically, the LTIR was measured by the measurement method described above, using the flatness measuring machine “Tropel FlatMaster™” manufactured by Corning Tropel Corporation.

In all of the samples, the third area density was measured. Specifically, the third area density was measured by the measurement method described above, using a PL imaging apparatus “SemiScope™ PLI-200” manufactured by Photon Design Corporation. In measuring the third area density, near-infrared objective lens 233 had a magnification of 4.5×. The measurement was performed at room temperature (27° C.).

Color image sensor 235 was a CCD image sensor. The CCD device was of a back-illuminated deep depletion type. The CCD image sensor was “eXcelon™” manufactured by Teledyne. The imaging wavelength range was 310 nm or more and 1024 nm or less. The device format was 1024 ch×1024 ch. The image area was 13.3 mm×13.3 mm. The device size was 13 μm×13 μm.

In all of the samples, the measured first area density, second area density and third area density were used to calculate each of the ratio of the third area density to the sum of the first area density and the second area density, and the ratio of the third area density to the first area density.

### (Measurement Results)

TABLE 1

| Number | Sample 1 | Sample 2 | Sample 3 | Sample 4 | Sample 5 | Sample 6 | Sample 7 |
|---|---|---|---|---|---|---|---|
| Area density of threading screw dislocations | 470 | 500 | 540 | 520 | 1340 | 870 | 200 |
| (TSDs) in first main surface (first area density) | | | | | | | |
| [/cm²] | | | | | | | |
| Area density of threading edge dislocations | 3250 | 4000 | 3500 | 4100 | 9060 | 5620 | 1870 |
| (TEDs) in first main surface (second area | | | | | | | |
| density) | | | | | | | |
| [/cm²] | | | | | | | |
| Sum of first area density and second area | 3720 | 4500 | 4040 | 4620 | 10400 | 6490 | 2070 |
| density | | | | | | | |
| [/cm²] | | | | | | | |
| Area density of voids after required amount of | 0.6 | 0.28 | 0.05 | 0.20 | 0.19 | 0.08 | 0.03 |
| polishing confirmation step | | | | | | | |
| [/cm²] | | | | | | | |
| Required amount of polishing | 30 | 45 | 60 | 45 | 60 | 60 | 60 |
| [μm] | | | | | | | |
| Amount of polishing by CMP | 3 | 3 | 3 | 8 | 3 | 3 | 3 |
| [μm] | | | | | | | |
| Total thickness variation (TTV) of silicon | 2.0 | 3.4 | 3.4 | 6.2 | 1.4 | 1.9 | 1.6 |
| carbide substrate | | | | | | | |
| [μm] | | | | | | | |
| Average value of LTIR of silicon carbide | 0.36 | 0.36 | 0.41 | 0.68 | 0.42 | 0.25 | 0.24 |
| substrate in outer circumferential regions | | | | | | | |
| [μm] | | | | | | | |
| Area density of blue light-emitting defects in | 1.75 | 0.94 | 0.39 | 0.88 | 1.98 | 0.83 | 0.18 |
| second main surface (third area density) | | | | | | | |
| [/cm²] | | | | | | | |
| Ratio of third area density to sum of first area | 0.047 | 0.021 | 0.010 | 0.019 | 0.019 | 0.013 | 0.009 |
| density and second area density | | | | | | | |
| [%] | | | | | | | |
| Ratio of third area density to first area density | 0.37 | 0.19 | 0.07 | 0.17 | 0.15 | 0.10 | 0.09 |
| [%] | | | | | | | |

When the amount of polishing by the mechanical polishing is excessively large, more polishing marks are formed on first main surface 1 of silicon carbide substrate 10. Accordingly, it is required to increase the amount of polishing by the CMP. In this case, the degree of sag of the outer circumferential portion of first main surface 1 increases because the outer circumferential portion is more likely to come into contact with the polishing solution in the CMP than the inner circumferential portion. In other words, each of the TTV and LTIR increases. According to the method for manufacturing silicon carbide epitaxial substrate 100 of the present embodiment, on the other hand, the amount of polishing by the mechanical polishing is the required amount of polishing determined in the required amount of polishing determination step (S20). Accordingly, excessive increase in the amount of polishing by the mechanical polishing can be suppressed, and increase in the amount of polishing by the CMP can be suppressed. As a result, increase in each of the TTV and LTIR can be suppressed.

As shown in Table 1, a comparison of sample 1 to sample 7 in terms of the TTV found that, when the amount of polishing by the CMP was 3 μm or less, the TTV was 6 μm or less. A comparison of sample 1 to sample 7 in terms of the LTIR found that, when the amount of polishing by the CMP was 3 μm or less, the average value of the LTIR in outer circumferential regions 60 was 0.6 μm or less. These results confirmed that reducing the amount of polishing by the CMP could suppress increase in each of the TTV and LTIR.

As shown in Table 1, a comparison of sample 1 to sample 7 in terms of the ratio of the third area density to the sum of the first area density and the second area density found that, when the area density of voids after the required amount of polishing determination step (S20) was 0.3/cm² or less, the ratio of the third area density to the sum of the first area density and the second area density was 0.03% or less. It was similarly found that, when the area density of voids after the required amount of polishing determination step (S20) was 0.2/cm² or less, the ratio of the third area density to the sum of the first area density and the second area density was 0.02% or less. It was similarly found that, when the area density of voids after the required amount of polishing determination step (S20) was 0.05/cm² or less, the ratio of the third area density to the sum of the first area density and the second area density was 0.01% or less.

As shown in Table 1, a comparison of sample 1 to sample 7 in terms of the ratio of the third area density to the first area density found that, when the area density of voids after the required amount of polishing determination step (S20) was 0.3/cm² or less, the ratio of the third area density to the first area density was 0.2% or less.

These results confirmed that, in the method for manufacturing the silicon carbide epitaxial substrate according to the present embodiment, when the area density of voids after the required amount of polishing determination step (S20) was 0.3/cm² or less, silicon carbide epitaxial substrate 100 having a small LTIR of silicon carbide substrate 10 and having a low area density of blue light-emitting defects 83 in second main surface 2 could be obtained.

It should be understood that the embodiments and examples disclosed herein are illustrative and non-restrictive in every respect. The scope of the present disclosure is defined by the terms of the claims, rather than the embodiments described above, and is intended to include any modifications within the scope and meaning equivalent to the terms of the claims.

### REFERENCE SIGNS LIST

1 first main surface; 2 second main surface; 3 third main surface; 4 fourth main surface; 5 fifth main surface; 6 interface; 7 orientation flat portion; 8 arc-shaped portion; 9 outer circumferential side surface; 10 silicon carbide substrate; 11 normal portion; 12 damaged portion; 20 silicon carbide epitaxial layer; 30 polishing apparatus; 31 polishing head; 32 abrasive supply unit; 33 abrasive; 34 polishing cloth; 35 surface plate; 37 support plate; 38 weight; 39 post; 41 first rotation axis; 42 second rotation axis; 43 center-side swing end; 50 square region; 60 outer circumferential region; 61 first outer circumferential region; 62 second outer circumferential region; 70 central region; 80 threading dislocation; 81 threading screw dislocation; 82 threading edge dislocation; 83 blue light-emitting defect; 84 void; 90 silicon carbide wafer; 99 dummy wafer; 100 silicon carbide epitaxial substrate; 101 first direction; 102 second direction; 103 third direction; 104 fourth direction; 111 first rotation direction; 112 second rotation direction; 113 swing direction; 200 color photoluminescence imaging apparatus; 220 excitation light generation unit; 221 light source unit; 222 light guiding unit; 223 filter unit; 230 imaging unit; 231 controller; 232 stage; 233 near-infrared objective lens; 235 color image sensor; D diameter; H1 first thickness; H2 second thickness; L0 least square plane; L1 first highest point plane; L2 first lowest point plane; L3 second highest point plane; L4 second lowest point plane; LE excitation light; LL photoluminescence light; P1 first highest point; P2 first lowest point; P3 second highest point; P4 second lowest point; T1 first highest point height; T2 first lowest point height; T3 second highest point height; T4 second lowest point height; W1 first length; W2 second length; 0 inclination angle.

1. A silicon carbide epitaxial substrate comprising:
a silicon carbide substrate having a first main surface; and
a silicon carbide epitaxial layer provided on the first main surface, wherein
the silicon carbide epitaxial substrate includes
one or more threading screw dislocations in the silicon carbide substrate,
one or more threading edge dislocations in the silicon carbide substrate, and
one or more blue light-emitting defects in the silicon carbide epitaxial layer,
the silicon carbide epitaxial layer has a second main surface located opposite to an interface between the silicon carbide substrate and the silicon carbide epitaxial layer,
the one or more blue light-emitting defects are exposed at the second main surface,
when photoluminescence light generated from the one or more blue light-emitting defects by irradiation of the one or more blue light-emitting defects with excitation light is represented in HSV color space, H is 180° or more and 230° or less, S is 60 or more and 170 or less, and V is 190 or more and 255 or less,
when the first main surface is divided into a plurality of square regions each having a side length of 10 mm, the plurality of square regions include a plurality of first outer circumferential regions located at an outermost circumference of the plurality of square regions, and a plurality of second outer circumferential regions in contact with the plurality of first outer circumferential regions,
an average value of LTIR of the silicon carbide substrate in the plurality of first outer circumferential regions and the plurality of second outer circumferential regions is 0.6 μm or less, and
when an area density of the one or more threading screw dislocations in the first main surface is a first area density, an area density of the one or more threading edge dislocations in the first main surface is a second area density, and an area density of the one or more blue light-emitting defects in the second main surface is a third area density, a ratio of the third area density to a sum of the first area density and the second area density is 0.03% or less.

2. The silicon carbide epitaxial substrate according to claim 1, wherein the silicon carbide substrate has a total thickness variation of 6 μm or less.

3. The silicon carbide epitaxial substrate according to claim 1, wherein the ratio of the third area density to the sum of the first area density and the second area density is 0.02% or less.

4. The silicon carbide epitaxial substrate according to claim 3, wherein the ratio of the third area density to the sum of the first area density and the second area density is 0.01% or less.

5. The silicon carbide epitaxial substrate according to claim 1, wherein a ratio of the third area density to the first area density is 0.2% or less.

6. The silicon carbide epitaxial substrate according to claim 1, wherein the first area density is 1500/cm² or less.

7. The silicon carbide epitaxial substrate according to claim 6, wherein the first area density is 500/cm² or less.

8. The silicon carbide epitaxial substrate according to claim 7, wherein the first area density is 100/cm² or less.

9. The silicon carbide epitaxial substrate according to claim 1, wherein the second area density is 10000/cm² or less.

10. The silicon carbide epitaxial substrate according to claim 9, wherein the second area density is 5000/cm2 or less.

11. The silicon carbide epitaxial substrate according to claim 10, wherein the second area density is 2000/cm² or less.

12. The silicon carbide epitaxial substrate according to claim 1, wherein the second main surface has a diameter of 150 mm or more.

13. The silicon carbide epitaxial substrate according to claim 1, wherein the silicon carbide substrate has an electrical resistivity of 10 mΩ·cm or more.
